(19) United States
(12) Patent Application Publication
(10) Pub. No.: US 2021/0389160 A1
(43) Pub. Date: Dec. 16, 2021

(54) SENSOR ARRANGEMENT

(71) Applicant: ZF Friedrichshafen AG, Friedrichshafen (DE)

(72) Inventor: Ralf Pfeifer, Diepholz (DE)

(73) Assignee: ZF Friedrichshafen AG, Friedrichshafen (DE)

(21) Appl. No.: 17/290,416

(22) PCT Filed: Oct. 23, 2019
(86) PCT No.: PCT/EP2019/078886

§ 371 Date: Apr. 30, 2021

(30) Foreign Application Priority Data
Oct. 31, 2018 (DE) 102018218673.1

(51) Int. Cl. G01D 5/14; H01H 19/14

(52) U.S. Cl. CPC G01D 5/14; H01H 19/14

(57) ABSTRACT

A sensor arrangement for controlling a function in a motor vehicle comprises an electric coil for providing a magnetic field; a magnetic field sensor; and a magnetic flux element for conducting the magnetic field between the coil and the magnetic field sensor. The magnetic flux element may be supported such that it can move, and shaped such that the magnetic field in the range of the magnetic field sensor is dependent on a position of the flux element. Furthermore, there may be a processor for determining the position of the flux element based on the magnetic field determined by means of the magnetic field sensor.

### RELATED APPLICATIONS

This application is a filing under 35 U.S.C. § 371 of International Patent Application PCT/EP2019/078886, filed Oct. 23, 2019, and claiming priority to German Patent Application 10 2018 218 673.1, filed Oct. 31, 2018. All applications listed in this paragraph are hereby incorporated by reference in their entireties.

### TECHNICAL FIELD

The present disclosure relates to a sensor arrangement. In particular, the present embodiments relates to a sensor arrangement in a safety-relevant application, e.g. for controlling a function in a motor vehicle.

### BACKGROUND

A function can be controlled in a motor vehicle that affects a driving function in the motor vehicle. The function can be controlled in particular by the driver of the motor vehicle by means of an input device that converts a mechanical movement of an actuation element into a control signal. If the function is controlled in an unintended manner, this can endanger the operational safety of the motor vehicle. The input device must function in a fail-safe manner to prevent malfunctioning.

Certain national or international standards regarding functional reliability must be complied with in this regard, e.g. a predetermined ASIL capability of the input device according to ISO 26262 or IEC 61508. There are various known measures for complying with these standards that frequently comprise a redundant configuration of one or more elements. Such an input device may be expensive.

### BRIEF DESCRIPTION OF THE DRAWINGS

Certain features, aspects, and advantages of the disclosed embodiments are shown in the drawings accompanying this description. The drawings are briefly described below.

FIG. 1 shows an input device;

FIG. 2 shows a flow chart for a method;

FIG. 3 shows an embodiment of a magnetic flux element;

FIG. 4 shows an exemplary temporal course of various measurements at a sensor arrangement; and

FIG. 5 shows a top view of an embodiment of a coil.

### DETAILED DESCRIPTION

A fundamental object of the present embodiments, and variations thereof, is to create a sensor arrangement and a control method for an inexpensive, fail-safe operation of a function in a motor vehicle.

According to a first aspect, a sensor arrangement for controlling a function in a motor vehicle comprises an electric coil that generates a magnetic field, a magnetic field sensor, and a magnetic flux element for conducting the magnetic field between the coil and the magnetic field sensor. The magnetic flux element is supported such that it can move, and is shaped such that the magnetic field within the range of the magnetic field sensor is dependent on a position of the flux element. There is also a processor for determining the position of the flux element on the basis of the magnetic field determined by means of the magnetic field sensor.

The coil can be in the form of a structure on a printed circuit board in particular, such that a special component is not needed. The coil can also be preferably attached beneath the magnetic field sensor. As a result, the strength of the magnetic field is advantageously exploited, such that a sufficient signal strength is generated in the magnetic field sensor to stimulate the magnetic field sensor with low amperages.

As a result, the position of the flux element can be reliably determined without touching it. The flux element can be part of an input device in a motor vehicle in particular, and the movement of the flux element can be limited mechanically, e.g. to a predetermined movement path, or to a displacement along or a rotation about a predetermined axis. The magnetic flux element can be asymmetrical, such that a change in the position or orientation of the flux element results in a change in the magnetic field detected by the magnetic field sensor.

This means that the costs for a permanent magnet can be spared. The strengths of the magnetic field are controlled for the purposes of a measurement. The arrangement can be better calibrated or adjusted to improve the measurement precision. The position can be determined by means of a constant magnetic field. The magnetic field sensor is also preferably a microelectronic or micromechanical component, such that it can be better connected to a processor in the form of a microcomputer. There are various designs for integrated sensors of this type.

It is proposed that the processor is also configured to alter a current flowing through the coil, and to determine whether a change in the magnetic field determined by means of the magnetic sensor corresponds to an expected change caused by the change in the current. In other words, the processor can check the functionality of the sensor arrangement in that the magnetic field determination is checked with magnetic fields of different strengths.

As a result, the sensor arrangement can satisfy requirements for a safety-relevant component, e.g. according to ISO 26262. The magnetic field sensor does not need to have a redundant design for this. By using standard components, costs for the sensor arrangement can be reduced. The safety level that can be obtained with the proposed dynamic principle may be higher than that of a homogenous redundancy. A producer of the sensor arrangement that purchases the magnetic field sensor can ensure the safety of the arrangement himself, without having to depend on a property of the sensor that he has no control over.

If the observed magnetic field is not within the expected, predetermined boundaries, an error signal can be output. It is also possible to redetermine the position of the flux element by altering the magnetic field formed by the coil. Alternatively, the position can also be determined by adjusting a measurement value for the magnetic field sensor in a predefined manner. This adjustment can comprise, in particular, a scaling of the measurement value.

In one embodiment, the magnetic flux element is shaped such that a strength of the magnetic field in the range of the magnetic field sensor is dependent on a position of the flux element, and the magnetic field sensor is configured to determine the strength of the magnetic field within its range. In another embodiment, the magnetic field element is shaped such that instead of, or in addition to the strength, a direction of the magnetic field within the range of the magnetic field sensor is dependent on a position of the flux element. The magnetic field sensor is configured to determine the direction of the magnetic field within its range for this. The determination of the direction can advantageously result in safer or reduced determination errors.

The flux element can move in relation to a predetermined axis, and the coil and the magnetic field can be offset to one another in relation to this axis. The flux element can be displaced along this axis, or it can rotate about this axis. A combined movement, e.g. along a helical line, is also conceivable. The axis preferably runs through the coil in the direction of the magnetic field therein. As a result of the axial offset, the flux element can receive the magnetic field provided by the coil where the flux density is greater, and thus conduct the magnetic flux toward the magnetic field sensor. As a result, a desired signal from the magnetic field sensor can be amplified.

The flux element can be shaped such that the width of a gap between the flux element and the magnetic field sensor is dependent on the position of the flux element. The width of the gap can control the strength of the magnetic field in the range of the magnetic field sensor, wherein a larger gap corresponds to a small magnetic field and a smaller gap corresponds to a large magnetic field. The position of the flux element can then be determined on the basis of the strength of the magnetic field. In addition, a direction of the magnetic field dependent on the position can also be incorporated in the determination of the position.

The magnetic field sensor can also be configured to determine the magnetic field along numerous different spatial directions. The magnetic field sensor can comprise separate devices for determining the magnetic field in each spatial direction. The strengths of the magnetic field in different spatial directions can be obtained separately by the magnetic field sensor. Alternatively, the direction and strength of the magnetic field can be determined by the magnetic field sensor as vector values, for example, and the components of these vectors can be obtained. In one embodiment, the magnetic field sensor is formed by a two or three dimensional sensor. The numerous devices result in a redundancy in the magnetic field sensor. If one of the devices malfunctions, the sensor arrangement can continue to function on the basis of another device. The magnetic field sensor is preferably attached such that a change in the position of the flux element alters the magnetic field at the magnetic field sensor in at least two spatial directions.

According to a second aspect, a method for controlling a function in a motor vehicle comprises steps for providing a magnetic field by means of an electric coil, determining a magnetic field within the range of a magnetic field sensor, wherein a magnetic flux element configured to conduct the magnetic field between the coil and the magnetic field sensor is supported such that it can move, wherein the magnetic flux element is shaped such that the magnetic field within the range of the magnetic field sensor is dependent on a position of the flux element, and determining the position of the flux element on the basis of the magnetic field determined by means of the magnetic field sensor.

The method can be executed entirely or in part on a sensor arrangement described herein. In particular, the method can be implemented by a processor in the sensor arrangement in the form of a microcomputer or microcontroller. The method can be obtained in the form of a computer program containing programming code. The computer program can be stored on a computer-readable data medium. Advantages or features of the method can also be attributed to the device described herein, and vice versa.

In a preferred embodiment, a current flowing through the coil can also be altered, and it is then determined whether a change in the magnetic field determined by the magnetic field sensor corresponds to an expected change caused by the change in current. Determination of the position is preferably alternated periodically with a determination of the functioning. The position can also be determined successively with respect to different magnetic fields in order to detect a defect, in which a signal from the magnetic field sensor is not dependent on the magnetic field provided by the coil in the expected manner, e.g. due to interference from an external magnetic field.

The current directions for determining the position of the flux element and checking the sensor arrangement can have opposing polarities. As a result, the sensor arrangement can be checked outside the normal measurement parameters. The probability of determining a defect can be increased as a result.

The present embodiments also comprises the use of a sensor arrangement according to the above description in a rotary switch in a vehicle to determine a rotational position of the rotary switch. The coil can be positioned along a rotational axis of the rotary switch for this. The magnetic flux element can be connected to a shaft or some other moving part of the rotary switch.

The present embodiments shall now be described in greater detail in reference to the attached drawings. Therein:

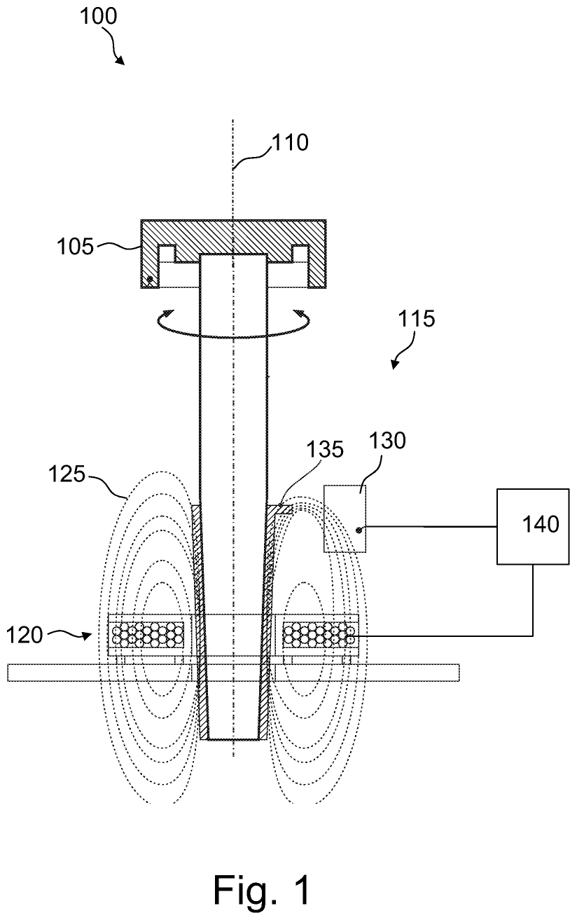

FIG. 1 shows a schematic illustration of an exemplary input device 100, configured in particular for use in a motor vehicle, in a longitudinal section. The input device 100 is configured to provide a signal indicating a mechanical actuation, and can be used to input a driver's desire to a device that can act on a function in the motor vehicle, in particular a movement. By way of example, the input device can be used to select or shift to a gear setting in a transmission that is part of a drive train in the motor vehicle.

The input device 100 comprises an actuation element 105 that can move in relation to an axis 110, and a sensor arrangement 115. In the present case, it is assumed that the actuation element 105 can move one-dimensionally in relation to the sensor arrangement 115. In the embodiment shown herein, the actuation element 105 can rotate about the axis 110, but it would also be possible for it to be displaced along the axis 110.

The sensor arrangement 115 comprises an electric coil 120 for providing a magnetic field 125, wherein the coil 120 is preferably attached such that it is substantially coaxial to the axis 110. The winding axis of the coil 120 is ideally the same as the axis 110, or at least parallel thereto. The sensor arrangement 1155 also comprises a magnetic field sensor 130 and a magnetic flux element 135 that is configured to conduct the magnetic field 125 between the coil 120 and the magnetic field sensor 130. For this, the flux element 135 is preferably made of a material with a low magnetic resistance, e.g. a soft magnetic iron, in particular with a permeability in the range of ca. 100 to 10,000.

The flux element 135 can be attached to the actuation element 105, e.g. by means of the conical clamp shown in the drawing, or by means of adhesive, or some other form of press-fit. This can also be a form-fitting or force-fitting attachment. The actuation element 105 is preferably made of a material with a high magnetic resistance, in particular with a permeability of ca. 1. The actuation element 105 can be paramagnetic or diamagnetic, and comprise, e.g., aluminum or a plastic. The high magnetic resistance makes the magnetic field 125 in the range of the magnetic field sensor 130 substantially independent of the properties of the actuation element 105. Instead, the magnetic field 125 at the magnetic field sensor 130 should only be dependent on the properties and position of the flux element 135. In another variation, the actuation element 105 and the flux element 135 are integrated such that the functions of the force transfer and the conducting of the magnetic field 135 are fulfilled by just one component.

The magnetic field sensor 130 is preferably attached such that it is axially offset to the coil 120. The flux element 135, likewise extending axially, guides or conducts the magnetic field 125 into the range of the magnetic field sensor 130. In an axial region facing the magnetic field sensor 130, the flux element 135 is configured such that the strength and/or direction of the magnetic field 125 at the magnetic field sensor 130 is dependent on the position of the moving flux element 135. In this embodiment, the flux element 135 comprises a radial projection that extends to a greater or lesser extent toward the magnetic field sensor 130, depending on the rotational position of the actuation element. The width of the gap between the flux element 135 and the magnetic field sensor 130, and therefore the strength of the magnetic field 125, can therefore be dependent on the rotational position of the actuation element 105. With an appropriate shape of the projection, the direction of the magnetic field 125 within the range of the magnetic field sensor 130 can also be dependent on the position of the flux element 135.

A processor 140 can be provided for determining the position of the flux element 135, or the actuation element 105 attached thereto. The processor 140 can then determine or direct a current through the coil 120, and receive a signal from the magnetic field sensor 130 that indicates a magnetic field 125 within its range.

The magnetic field sensor 130 can be based, e.g., on the magnetoresistive effect, in which the electric resistance of a material is altered by applying an external magnetic field, e.g. anisotropic magnetoresistance (AMR), giant magnetoresistance (GMR), colossal magnetoresistance effect (CMR), tunnel magnetoresistance (TMR) or the planar Hall effect. The magnetic field sensor 130 is preferably an integrated semiconductor. As a result, it can determine the direction and/or strength of the magnetic field 125 in one or more spatial directions.

The spatial directions can be at right angles to one another in pairs, and also referred to as dimensions. In particular, the magnetic field sensor 130 can be configured to determine the magnetic field 125 in two (2D) or three (3D) dimensions. A transmitted signal can comprise the strengths of the magnetic field 125 along the individual spatial directions, or it can be output as a vector indicating extent and direction with respect to the spatial directions. If the magnetic field sensor 130 is configured to determine the magnetic field 125 in more than one spatial direction, it is preferred that the magnetic field sensor 130 is oriented in the magnetic field 125 such that a change in the magnetic field 125 caused by a change in the position of the flux element 130 relates to more than one spatial direction, ideally to all spatial directions that are plotted.

It is proposed that the processor 140 is configured to check the sensor arrangement 115 instead of or in addition to determining the position. For this, it can alter, in particular, the magnetic field 125 provided by the coil 120 by adjusting the current flowing through the coil 120. It can determine the magnetic field 125 in the range of the magnetic field sensor 120 before and after the change. Based on the two measurements, it is possible to determine whether a change corresponds to the expected magnetic field 125 measurement due to the change in current. The magnetic field sensor 130 is preferably configured to determine the magnetic field 125 either digitally, in a sufficient number of steps, or in an analog form. A binary display magnetic field sensor 130 is not adequate for the check, even if it is only necessary to distinguish two positions of the flux element 135 from one another.

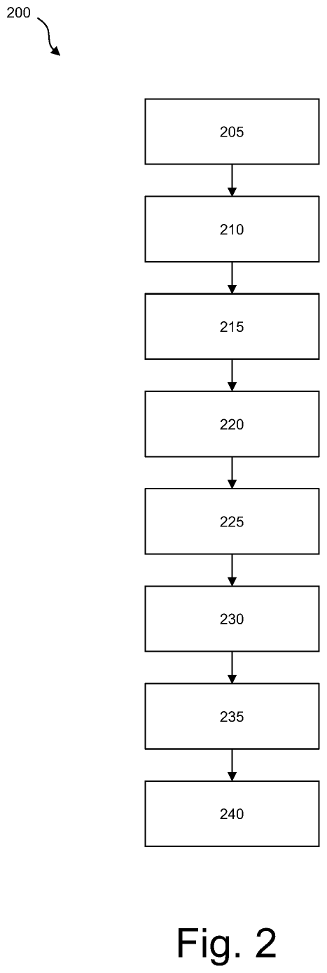

FIG. 2 shows a flow chart for a method 200. The method 200 can be executed on the sensor arrangement 115, and comprises, strictly speaking, a first method for determining the position of the flux element 135 and an interwoven second method for checking the functionality of the sensor arrangement 115. Because the methods share certain steps, and both results are normally relevant, the method 200 provides both results, even if the first and second methods can each be carried out independently.

In a first step 205, a first current is directed through the coil 120. In step 210, a first magnetic field 125 is determined in the range of the magnetic field sensor 130, in that a measurement value is obtained from the magnetic field sensor 130. A predetermined time period can elapse between the activation and the measurement, while waiting for the magnetic field 125 to become stable. The first magnetic field 125 that is determined can be saved. In an optional step 215, the position of the flux element 135 can be determined on the basis of the first determined magnetic field 125. This position can be output, e.g. to a data bus or a control unit.

In step 220, a second current is directed through the coil 120. The second current differs from the first current, and is also preferably not zero. In step 225, the magnetic field 125 is determined a second time. The steps 220 and 225 correspond substantially to steps 205 and 210.

To check the sensor arrangement 115, it can be determined in step 230 how the magnetic field 125 was to change due to the change in the current through the coil between the steps 205 and 220. The expected change in the magnetic field 125 due to the change in current can be previously determined empirically with an identical sensor arrangement 115. In doing so, the position of the flux element 135 can also be taken into account. The results can be recorded in the form of a table, a graph, or a grid. Alternatively, the expected change can also be analytically determined on the basis of a physical model of the sensor arrangement 115. In step 235, the change in the magnetic field 125 measurement is determined.

It is determined in step 240 whether the two determinations correspond to one another. In particular, it is possible to determine whether they differ from one another by more than a predetermined amount. The consideration can comprise a strength and/or direction of the magnetic field 125 determined at the magnetic field sensor. Strengths along predetermined spatial directions can also be checked. If the differences between the changes are greater than a predetermined difference, an error signal can be output.

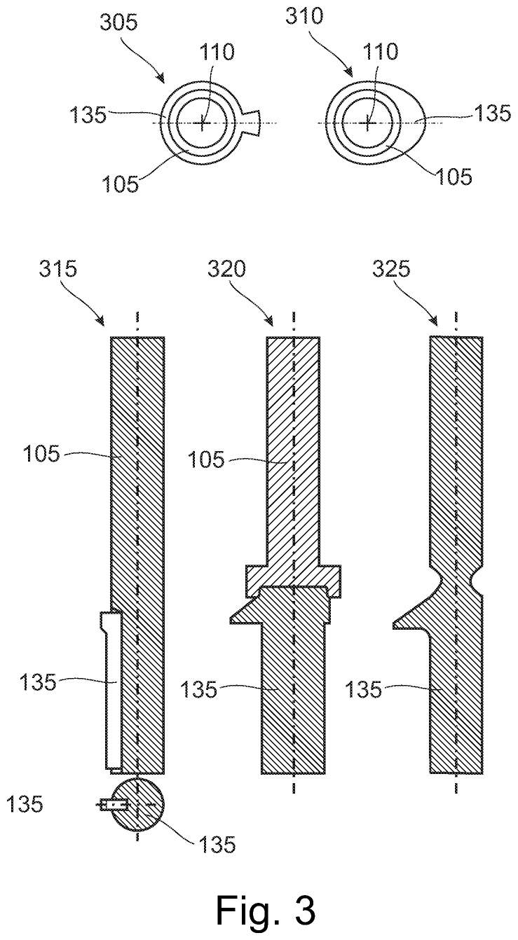

FIG. 3 shows exemplary embodiments of a magnetic flux element 135. These flux elements 135 are each configured for a rotary actuation about the axis 110, which has also been described in reference to FIG. 1.

A first embodiment 305 shows an axial view or a cross section in the range of the magnetic field sensor 130. The flux element 135 is substantially radially symmetrical and comprises a radial projection that extends radially outward in the manner of an arc segment over a predetermined angle and a predetermined distance.

A second embodiment 310 is shown in a similar view, in which the flux element 135 forms a cam in relation to the axis 110. Alternatively, the flux element 135 in this view can also have the form of an eccentric disk.

A third embodiment 315 of the flux element 135 is shown in a longitudinal section and in an axial perspective from the end. The flux element 135 is oriented like that illustrated in FIG. 1, such that a lower section lies in the region of the coil 110, and a middle or upper section lies in the range of the magnetic field sensor 130. The actuation element 105 forms a shaft with a radial groove running in the axial direction. The flux element 135 lies in this groove, which is substantially rectangular, e.g. in the form of a sheet, spring, or shim. The actuation element 105 has a high magnetic resistance, and the flux element 135 has a low magnetic resistance.

A fourth embodiment 320 of the flux element 135 is shown in a longitudinal section. The actuation element 105 borders at the end on the magnetic flux element 135, which has a radial projection at an axial position lying in the range of the magnetic field sensor 130. The projection preferably extends radially at an axial side facing the coil 120; a slanted transition running radially inward can be formed on an opposing axial side, as shown in the drawing. The actuation element 105 in this embodiment also preferably has a high magnetic resistance, and the flux element 135 has a low magnetic resistance. The flux element 135 can transfer torsional forces when the actuation element 105 is actuated. The two elements 105, 135 can be connected to one another in a material-bonded manner, e.g. in that the actuation element made of plastic is glued or bonded to the flux element 135. A form-fitting force transfer is likewise possible, in particular along a polygonal periphery.

A fifth embodiment 325 of the flux element 135 is also shown in a longitudinal section. A section thereof, extending in the axial direction of the coil 110 is cylindrical and borders on a section with a projection, similar to the fourth embodiment 320. There can be a radial indentation, constriction, or narrowing of the flux element 135 on the other axial side of the projection, which exposes the magnetic flux in a material with an increased resistance, in order to promote a radial spreading of the magnetic field 125 toward the projection. In this embodiment, the flux element 135 can be an integral part of the actuation element 105. The increased magnetic resistance at the narrowing can indicated the transition between the two elements 105, 135 in this case. In another variation, two separate elements 105, 135 can also be connected axially to one another, as is the case in the fourth embodiment 320.

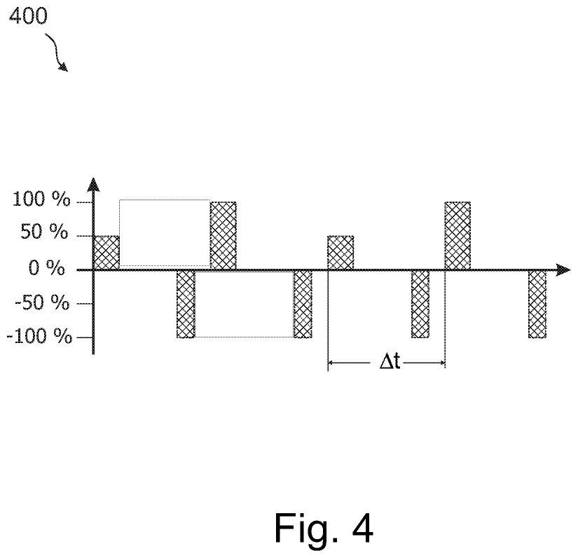

FIG. 4 shows an exemplary temporal course 400 of various measurements taken at a sensor arrangement 115. Time t is plotted on the horizontal axis, and the current I passing through the coil 110 is plotted on the vertical axis. A deformation of the signal due to the inductivity of the coil 110 is ignored in the illustration.

The position of the flux element 135 is determined at preferably uniform increments □t, for which a positive current is conducted through the coil 110 for a predetermined time. Optionally, successive measurements are taken at currents of different strengths; in this embodiment, the current alternates between 50% and 100% of a predetermined value. Other values, or currents of more than two different strengths can also be used. The current can also change from positive to negative, or it can always be negative.

The sensor arrangement 114 can be checked between measurements, during which the current has a different polarity in the present embodiment than that used for determining the position. The check is preferably made at 100% of the predetermined amperage, in order to obtain a clear result. The duration of the position determination or the check is mainly dependent on how quickly a predetermined magnetic field 125 can be formed, and how long the magnetic field sensor 130 requires for a determination. A period □t can be selected based on a desired measurement frequency, and last ca. 5-30 ms in a typical application in a motor vehicle. Pauses are preferably taken between the measurements or checks. In this embodiment, the pauses within a period □t are approximately three times as long as the combined measurement periods.

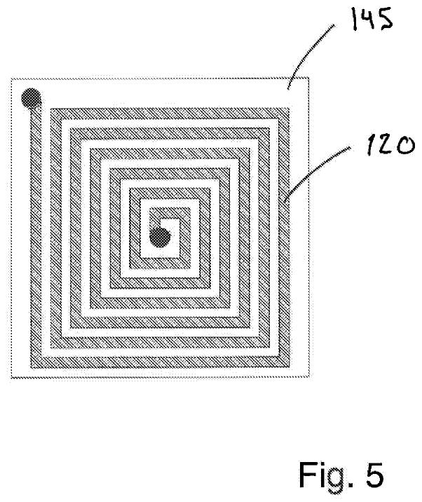

FIG. 5 shows a top view of an embodiment of a coil for a sensor arrangement 115 according to one embodiment of the present embodiments. The coil 120 is a printed coil on a printed circuit board 145. The coil 120 can be used for the dynamic position determination. Because the coil 120 now forms a structure on the printed circuit board 145, the costs for a wound coil can be spared. Instead, the coil 120 is generated during production of the printed circuit board 145, without added costs.

### REFERENCE SYMBOLS

100 input device
105 actuation element
110 axis
115 sensor arrangement
120 electric coil
125 magnetic field
130 magnetic field sensor
135 magnetic flux element
140 processor
200 method
205 directing first current
210 determining first magnetic field
215 determining position, providing position
220 directing second current
225 determining second magnetic field
230 determining target change in magnetic field
235 determining actual change in magnetic field
240 do the changes correspond to one another?
305 first embodiment
310 second embodiment
315 third embodiment
320 fourth embodiment
325 fifth embodiment
400 course

1. A sensor arrangement for controlling a function in a motor vehicle, wherein the sensor arrangement comprises:
an electric coil for conducting a magnetic field;
a magnetic field sensor;
a magnetic flux element for conducting the magnetic field between the electric coil and the magnetic field sensor,
wherein the magnetic flux element is supported such that it can move, and shaped such that the magnetic field in a range of the magnetic field sensor is dependent on a position of the magnetic flux element; and
a processor for determining the position of the magnetic flux element based on the magnetic field determined by the magnetic field sensor.

2. The sensor arrangement according to claim 1, wherein the processor is configured to alter a current flowing through the electric coil and determine whether a change in the magnetic field determined by the magnetic field sensor corresponds to a change expected due to the change in the current.

3. The sensor arrangement according to claim 1, wherein the magnetic flux element is formed such that a direction of the magnetic field in the range of the magnetic field sensor is dependent on a position of the magnetic flux element, and the magnetic field sensor is configured to determine the direction of the magnetic field in its range.

4. The sensor arrangement according to claim 1, wherein the magnetic flux element can move in relation to a predetermined axis, and the electric coil and the magnetic field sensor are offset axially in relation to this axis.

5. The sensor arrangement according to claim 1, wherein the magnetic flux element is shaped such that a width of a gap between the magnetic flux element and the magnetic field sensor is dependent on the position of the magnetic flux element.

6. The sensor arrangement according to claim 1, wherein the magnetic field sensor is configured to determine the magnetic field along numerous different spatial directions.

7. The sensor arrangement according to claim 6, wherein the magnetic field sensor is attached such that with a change in the position of the magnetic flux element, the magnetic field at the magnetic field sensor changes along at least two spatial directions.

8. The sensor arrangement according to claim 1, wherein the electric coil forms a structure on a printed circuit board.

9. A method for controlling a function in a motor vehicle, comprising:
conducting a magnetic field with an electric coil;
a observing the magnetic field within a range of a magnetic field sensor with the magnetic field sensor,
wherein a magnetic flux element configured to conduct the magnetic field between the electric coil and the magnetic flux element is supported such that it can move,
wherein the magnetic flux element is shaped such that the magnetic field in the range of the magnetic field sensor is dependent on a position of the magnetic flux element; and
determining the position of the magnetic flux element based on the magnetic field determined by the magnetic field sensor.

10. The method according to claim 9, wherein a current flowing through the electric coil is also altered, the method further comprising determining whether a change in the magnetic field determined by the magnetic field sensor corresponds to an expected change due to the change in the current.

11. The method according to claim 9, wherein current directions for determining the position of the magnetic flux element and determining the change exhibit opposing polarities.

12. (canceled)

13. The method of claim 9, further comprising determining a setting of a rotary switch based on the determined position of the magnetic flux element.

14. A rotary switch system, comprising:
a rotary switch coupled to a sensor arrangement, wherein the sensor arrangement comprises:
an electric coil for conducting a magnetic field;
a magnetic field sensor;
a magnetic flux element for conducting the magnetic field between the electric coil and the magnetic field sensor,
wherein the magnetic flux element is supported such that it can move, and shaped such that the magnetic field in a range of the magnetic field sensor is dependent on a position of the magnetic flux element; and
a processor for determining the position of the magnetic flux element based on the magnetic field determined by the magnetic field sensor.

15. The rotary switch according to claim 14, wherein the processor is configured to alter a current flowing through the electric coil and determine whether a change in the magnetic field determined by the magnetic field sensor corresponds to a change expected due to the change in the current.

16. The rotary switch according to claim 14, wherein the magnetic flux element is formed such that a direction of the magnetic field in the range of the magnetic field sensor is dependent on a position of the magnetic flux element, and the magnetic field sensor is configured to determine the direction of the magnetic field in its range.

17. The rotary switch according to any claim 14, wherein the magnetic flux element can move in relation to a predetermined axis, and the electric coil and the magnetic field sensor are offset axially in relation to this axis.

18. The rotary switch according to any claim 14, wherein the magnetic flux element is shaped such that a width of a gap between the magnetic flux element and the magnetic field sensor is dependent on the position of the magnetic flux element.

19. The rotary switch according to any claim 14, wherein the magnetic field sensor is configured to determine the magnetic field along numerous different spatial directions.

20. The rotary switch according to claim 19, wherein the magnetic field sensor is attached such that with a change in the position of the magnetic flux element, the magnetic field at the magnetic field sensor changes along at least two spatial directions.

21. The rotary switch according to any claim 14, wherein the electric coil forms a structure on a printed circuit board.
